(19) United States
(12) Patent Application Publication
(10) Pub. No.: US 2004/0255442 A1
(43) Pub. Date: Dec. 23, 2004

(54) Methods and apparatus for processing workpieces

(76) Inventors: James McDiarmid, Dana Point, CA (US); Daniel L. Messineo, Fremont, CA (US)

Correspondence Address: LARRY WILLIAMS, 3645 MONTGOMERY DR, SANTA ROSA, CA, 95405-5212, US

(21) Appl. No.: 10/465,537

(22) Filed: Jun. 19, 2003

(51) Int. Cl. H01L 21/00; H01L 21/64

(52) U.S. Cl. 29/25.01

(57) ABSTRACT

An apparatus that is suitable for processing a workpiece. The apparatus is capable of raising, lowering, and rotating the workpiece as part of at least one of processing the workpiece, loading the workpiece into a process chamber, and unloading the workpiece from the process chamber.

### CROSS-REFERENCE

This application is related to U.S. Pat. No. 6,326,584; the content of U.S. Pat. No. 6,326,584 is incorporated herein in its entirety by this reference.

### BACKGROUND

This invention relates to methods and apparatus for processing workpieces, more particularly, for positioning and rotating workpieces such as semiconductor wafers for electronic device fabrication.

The fabrication of products such as electronic devices and optical devices typically requires processing the workpiece in process chambers. The process chambers are configured so as to be capable of producing the process conditions needed for the particular processes. For some applications, the process conditions are rather harsh such as possibly requiring high temperature operation. For other applications, the process conditions require the process chamber to be capable of operating with minimum contamination from ambient air or from particulates. It is also common for the process conditions to include operation at sub-atmospheric pressures.

As a result of the operating requirements, an important aspect of the process is the capability of loading the workpiece into the process chamber and unloading the workpiece from the process chamber. In addition, for some applications it is also desirable or necessary for the workpiece to be rotated during the actual process step. This means that the rotation capability may be necessary during the extreme conditions of the process step. Loading and unloading the workpiece typically requires raising and lowering the workpiece so as to transfer the workpiece between a workpiece carrier and a susceptor for holding the workpiece in the process chamber.

The standard technology for raising and lowering a workpiece such as a semiconductor wafer often uses a metal bellows in order to maintain properly sealed conditions. The use of metal bellows can present a problem such as poor heat transfer characteristics so temperature control is difficult. Another problem associated with metal bellows is possible contaminants from the release of adsorbed gases and cause leaks. Furthermore, bellows can be expensive and unreliable because they can easily wear out and begin to leak after repeated use.

There are standard technologies that do not require a bellows for raising and lowering the workpiece. However, these technologies can be complicated, can be difficult to maintain, and may be bulky. In order to meet the requirements, it is desirable for the process equipment to be highly reliable and require no maintenance or easy maintenance. Consequently, it is difficult for the standard technology to meet the desired requirements.

Additional descriptions of some of the standard technologies can be found in the patent and scientific literature. For some examples, see United States patents U.S. Pat. No. 5,140,714, U.S. Pat. No. 5,772,773, U.S. Pat. No. 5,993,557, and U.S. Pat. No. 6,106,582.

There are numerous applications requiring reliable and efficient methods and apparatus for processing workpieces such as semiconductor wafers. Unfortunately, typical apparatus for wafer lift and rotation have characteristics that are unsatisfactory for some current applications and future applications. There is a need for systems with workpiece lift and rotation capabilities that are simple to operate and simple to maintain.

### SUMMARY

This invention seeks to provide methods and apparatus that can overcome one or more deficiencies in known methods and apparatus for providing motion to a workpiece. One aspect of the present invention includes an apparatus for generating rotational and translational motion for a substrate. The apparatus includes a susceptor for holding the substrate, a rotatable shaft connected with the susceptor, and a rotary motion source connected with the shaft for causing rotation of the shaft. The apparatus also includes a linear actuator and a lever mechanism connected between the shaft and the linear actuator so that linear motion generated by the actuator can be coupled to the shaft by the lever mechanism.

It is to be understood that the invention is not limited in its application to the details of construction and to the arrangements of the components set forth in the following description or illustrated in the drawings. The invention is capable of other embodiments and of being practiced and carried out in various ways. In addition, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out aspects of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

The above and still further features and advantages of the present invention will become apparent upon consideration of the following detailed descriptions of specific embodiments thereof, especially when taken in conjunction with the accompanying drawings.

### DESCRIPTION OF THE DRAWINGS

FIG. 1 is a cross-sectional side view of an embodiment of the present invention.

FIG. 2 is a cross-sectional side view of an embodiment of the present invention.

FIG. 3 is a cross-sectional side view of an embodiment of the present invention.

FIG. 4 is a top view of a lever arm for an embodiment of the present invention.

FIG. 5 is a side view of a lever arm for an embodiment of the present invention.

FIG. 6 is a side view of an embodiment of the present invention.

FIG. 7 is a cross-sectional side view of an embodiment of the present invention.

FIG. 8 is a cross-sectional side view of an embodiment of the present invention.

FIG. 9 is a side view of a piston with a stop mechanism for an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION

The operation of embodiments of the present invention will be discussed below in the context of processing substrates such as semiconductor wafers for electronic device fabrication. It is to be understood, however, that embodiments in accordance with the present invention may be used with essentially any workpiece-processing step that requires linear translation motion and rotation of the workpiece in a process chamber.

The present invention now will be described more fully hereinafter with reference to the accompanying drawing, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

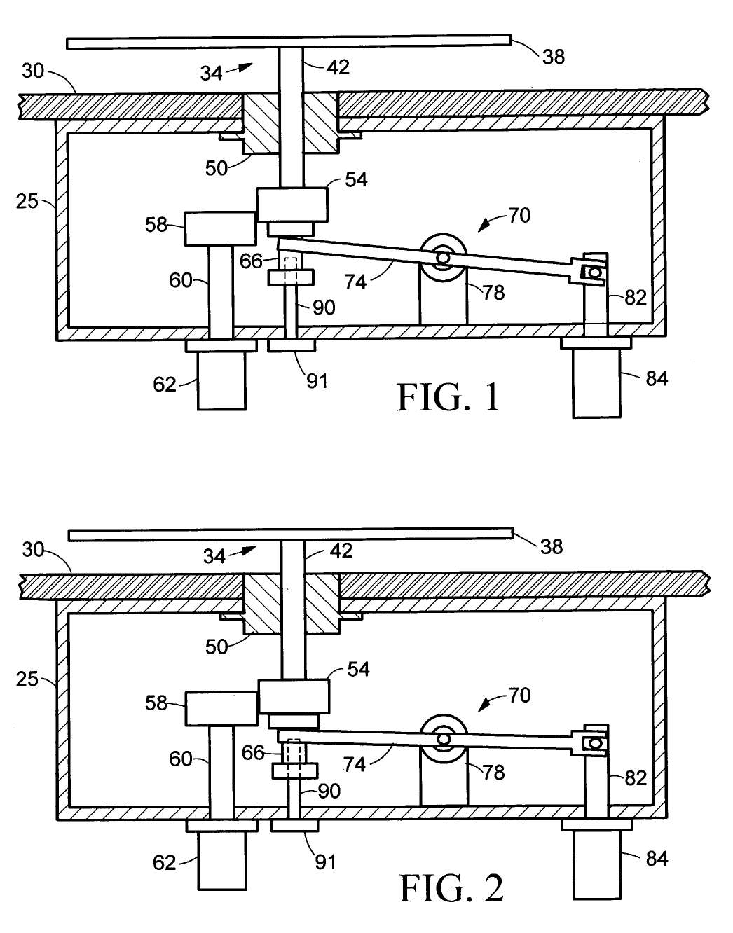

Reference is now made to FIG. 1 wherein there is shown an apparatus for processing a workpiece such as a semiconductor wafer. The apparatus includes a housing 25. Housing 25 is shown in cross-section so as to show the interior of housing 25. Also shown is a portion of a bottom surface 30 of a process chamber. Bottom surface 30 is shown in cross-section. Housing 25 is connected with bottom surface 30. Bottom surface 30 has a hole and housing 25 has a hole. The hole in bottom surface 30 and the hole and housing 25 are arranged so that they are adjacent. FIG. 1 also shows a bushing 50. Bushing 50 fits into at least one of the hole in bottom surface 30 and the hole in housing 25. FIG. 1 shows bushing 50 held in the hole in bottom surface 30 and the hole in housing 25. Bushing 50 has an axial bore. Bushing 50 may comprise materials such as plastics, metals, and other materials commonly used for bushings. Bushing 50 may also include surface coatings for purposes such as friction reduction and wear reduction.

A wafer support 34 is arranged so as to be capable of supporting the wafer in the process chamber. Wafer support 34 includes a disk 38 having a substantially planar area for contacting the backside of the wafer. Disk 38 may also be referred to as a susceptor. In a preferred embodiment, the area of wafer support 34 contacting the wafer, i.e. disk 38, is smaller than the area of the wafer so as to facilitate loading and unloading the wafer. Wafer support 34 further includes a wafer holder stem 42 connected substantially at the center of disk 38, at about a 90-degree angle. In preferred embodiments, stem 42 and disk 38 are sections of a single body; in other words, wafer support 34 is a singe piece that includes stem 42 and disk 38. Stem 42 extends from disk 38 through the hole in process chamber bottom surface 30 by way of the bore in bushing 50. Bushing 50 is arranged to allow rotary motion of stem 42 and up-and-down motion of stem 42 while holding stem 42 in a substantially stable orientation.

Wafer support 34 is coupled to a rotary motion source to allow rotation of wafer support 34 so that the wafer can be rotated during processing. In one embodiment, rotary motion can be coupled to wafer support 34 using spur gears. FIG. 1 shows spur gear 54 connected with stem 42. A second spur gear, spur gear 58, is engaged with spur gear 54. A shaft 60 for a rotary motion feedthrough 62 is coupled to housing 25 so as to provide a source of rotary motion to the interior of housing 25.

Rotary motion feedthroughs are well known and are commercially available. Typically, a rotary motion feature is attached to a housing at a hole in the housing so that the shaft of the rotary motion feed through extends through the hole in the housing.

Spur gear 58 is connected with shaft 60 so that rotary motion of shaft 60 causes rotary motion for spur gear 58. The rotary motion of spur gear 58 is coupled to spur gear 54 for rotating the wafer.

The use of spur gears for coupling rotary motion is but one option selected from numerous options. Other rotary motion coupling mechanisms that are suitable for embodiments of the present invention are mechanisms that use belts, mechanisms that use chains, methods that use magnetic coupling, and combinations thereof. Rotary motion coupling mechanisms are well known to those of ordinary skill in the art.

The apparatus shown in FIG. 1 is also capable of causing up-and-down motion of wafer support 34. Preferably, the up-and-down motion can be effected while wafer support 34 is still coupled to the rotary motion source. The embodiment shown in FIG. 1 achieves the up-and-down motion of wafer support 34 using a lever mechanism 70. An example of a suitable lever mechanism includes an elongated member such as a lever arm 74 and a structure for holding the lever arm such as a pivot bearing 78. Lever arm 74 may be made of a variety of materials: some typical examples are metals and polymers. In a preferred embodiment, lever arm 74 comprises a material such as TEFLON. An actuator such as a linear actuator is connected with the lever mechanism to provide motion for the lever. FIG. 1 shows a linear actuator 82 connected with a driver or other source of motion such as an air piston 84. The first end of lever arm 74 is connected with stem 42; the connection may be a direct connection or an indirect connection such as via a bearing or a bushing. The second end of lever arm 74 is connected with linear actuator 82.

In preferred embodiments, the contact friction between lever arm 74 and stem 42 is reduced. For instance, a system of ball bearings may be used to reduce friction. More specifically, a rotation bearing can be included with stem 42 to reduce the contact friction with lever arm 74. As another option, lever arm 74 may include a low friction coating such as specialty coatings that are well known to those of ordinary skill in the art.

The embodiment shown in FIG. 1 includes a bushing 66 having an axial bore. Bushing 66 has two large diameter sections separated by a small diameter section. Bushing 66 is connected with stem 42 so that the axis of stem 42 is aligned with the axis of bushing 66. Bushing 66 and stem 42 are connected so that an upward or a downward force acting on bushing 66 is also transferred to stem 42. The embodiment also includes a bearing 90 having an elongated small diameter section. Preferably, bearing 90 also has an axial bore through the small diameter section. The small diameter section of bearing 90 is sized so that at least a portion of bearing 90 slidably fits into the bore of bushing 66. In other words, part of bearing 90 is positioned substantially concentrically within the axial bore of bushing 66. One end of bearing 90 is connected with housing 25 so that bushing 66 continually engages the opposite end of bearing 90 while bushing 66 is connected with stem 42 so that bearing 90 provides alignment and further stabilizes stem 42 and, consequently, wafer support 34.

FIG. 1a shows a cross-sectioned side view of a configuration for bushing 66 and bearing 90. Bushing 66 and bearing 90 are essentially the same as that described for FIG. 1. In addition, FIG. 1a shows small diameter section 66a and large diameter section 66b of bushing 66. FIG. 1a also shows a portion 90a of bearing 90 for connecting bearing 90 to housing 25.

In preferred embodiments, housing 25 is sufficiently gas tight so as to substantially prevent the leakage of air into the interior of housing 25 during operation. Standard vacuum and gas sealing techniques can be used in making housing 25 substantially leak tight. As specific examples, gaskets and o-ring seals can be used to connect rotary motion feedthrough 62, air piston 84, and other items with housing 25. In addition, gaskets and o-ring seals can be used to connect housing 25 with the process chamber. The techniques of vacuum and gas sealing are well known in the art and will not be discussed in detail here. The gaskets and o-ring seals are not shown in the Figures of the present application.

To further prevent the leakage of air into the interior of housing 25, a purge gas connection is provided to housing 25 for flowing a purge gas such as an inert gas into housing 25. In preferred embodiments, the purge gas connection is made at location 91 so as to provide gas to the bore of bearing 90. Another advantage of providing a purge gas is that the purge gas can aid in cooling the housing and components therein.

As an option, bushing 50 may have a slot that extends substantially along its axial length and extending from the inner diameter to the outer diameter. The purpose of the slot is to provide relief from thermal expansion stresses that can occur with the use of dissimilar materials. Specifically, the slot provides space to accommodate the thermal expansion of at least one of stem 42, bushing 50, and bottom surface 30 for high temperature wafer processes. As a result of using a slot in bushing 50, stem 42 can be held tighter by bushing 50 without concern about hindering the rotation of wafer support 34 during high temperature processing.

In preferred embodiments, the slot is provided so as to avoid having a straight optical path through the length of the slot. This configuration can be important for high temperature processes where is desirable to avoid transmitting thermal radiation from the process chamber to the components in the housing. In one embodiment, the slot is provided at an angle to the axis of the bushing. In another embodiment, the slot is provided so as to have one or more turns to prevent a direct optical path through the length of the slot.

Another possible function of the slot is to allow the purge gas to exit housing 25. In other words, at least a portion of the purge gas provided to housing 25 can escape from housing 25 into the process chamber. Related to the flow of purge gas through the slot, another function of the slot is to facilitate cooling of the bushing with the escaping purge gas.

For processing wafers at elevated temperatures, it is preferable for wafer support 34 to comprise a thermally refractory material such as silicon carbide, graphite, silicon nitride, aluminum nitride, and quartz. However, if the processes do not involve high temperatures then it is possible to use standard materials that are typically used in low or moderate temperature semiconductor process equipment such as aluminum and steel.

The embodiment shown in FIG. 1 is depicted with wafer support 34 in the raised position. The raised position is produced by having linear actuator 82 retracted so as to pull down on the second end of lever arm 74. In response, the first end of lever arm 74 moves up and causes an upward force on bushing 66; the upward force is transferred through bushing 66 to stem 42 which places wafer support 34 in the raise the position. The use of spur gears as described for FIG. 1 allows wafer support 34 to be raised or lowered while spur gear 54 remains engaged with spur gear 58.

FIG. 2 also illustrates the embodiment shown in FIG. 1. In FIG. 2, the embodiment is depicted with wafer support 34 in the lowered position. The lowered position is produced by having linear actuator 82 extended so as to push up on the second end of lever arm 74. In response, the first end of lever arm 74 is moved down which produces a downward force on stem 42 which places wafer support 34 in the lowered position.

For some embodiments of the present invention, stem 42 may be a simple rod comprising the materials mentioned earlier. However, a simple rod may not provide adequate functionality for some applications of embodiments of the present invention. An improved wafer support stem may be advantageous in terms of operation and maintenance of embodiments of the present invention.

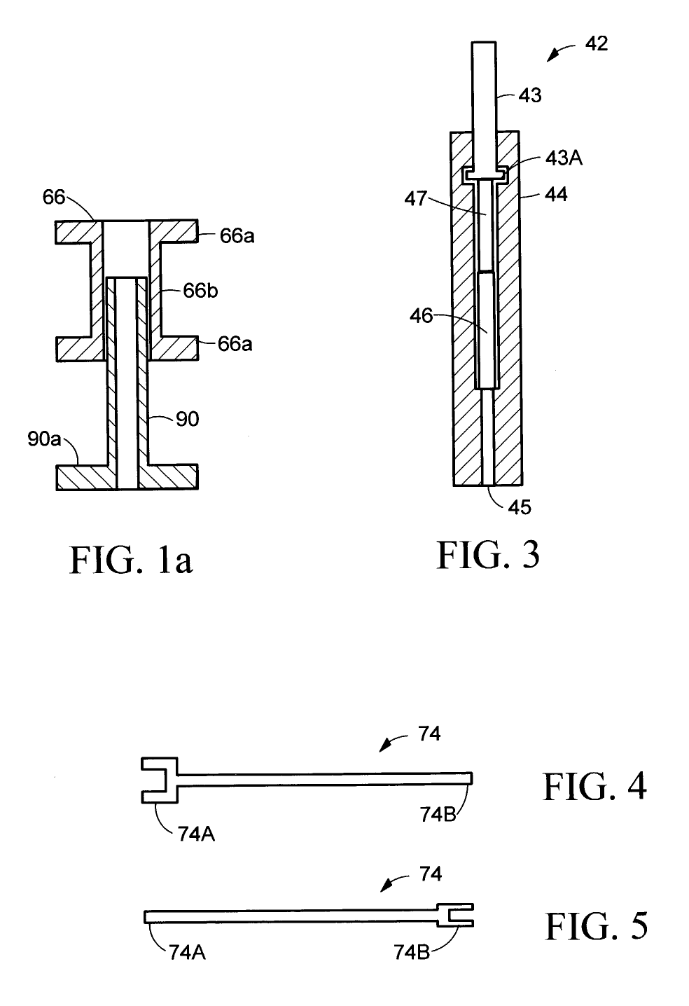

Reference is now made to FIG. 3 wherein there is shown an alternative embodiment of stem 42. FIG. 3 shows stem 42 having a first bayonet section 43 and a second bayonet section 44 configured to allow a bayonet-type connection between section 43 and section 44. FIG. 3 shows a cross-sectional view of section 44. One end of section 43 has at least one radial protrusion 43A; the opposite end of section 43 is connected with a disk 38 as described for the embodiment in FIG. 1. Section 44 includes a bore such as an axial bore 45 and at least one slot along at least a section of the bore so as to form a keyway for receiving the end of first bayonet section 43 and protrusion 43A. The slot is essentially a recess formed in the interior surface of the bore. The bore and the slot are sized so as to allow at least a partial rotation of section 43 within a portion of section 44 for the bayonet-type connection.

Preferably, the slot includes a first region for allowing protrusion 43A to slide in and out of section 44 as the end of section 43 slides in and out of section 44. The slot includes a second region connected with the first region. The second region has dimensions that allow protrusion 43A to be rotated into the second region so as to form the bayonet-type connection between section 43 and section 44.

In other words, the end of section 43 having protrusion 43A can be inserted a distance into section 44 and rotated an amount so that section 43 and section 44 are connected with a bayonet-type connection. Section 43 and section 44 can be disconnected by rotating section 43 and withdrawing section 43 from section 44.

In a preferred embodiment, a mechanism is provided for maintaining a contact force between section 43 and section 44. For the embodiment shown in FIG. 3, a spring 46 and a plunger 47 are disposed substantially within bore 45 of section 44. Spring 46 and plunger 47 are configured to apply a contact force between section 43 and section 44. Specifically, spring 46 and plunger 47 operate together to function as a spring-loaded plunger mechanism that provides a force between section 44 and section 43. The force provided by spring 46 and plunger 47 aids in stabilizing section 43. As a result of the added stability, section 43 and, consequently, disk 38 may be less susceptible to vibrations.

The embodiment of stem 42 shown in FIG. 3 depicts bore 45 extending through the full-length of section 44. This particular configuration is optional and is not required for all embodiments of the present invention. However, for some applications involving high temperature processing it may be advantageous to have bore 45 extend through the entire length of section 44 to facilitate cooling of stem 42. In some preferred embodiments the purge gas flow provided to housing 25 may be directed toward bore 45 to further facilitate cooling of stem 42.

The bayonet-type connection for stem 42 can be advantageous in matters such as system maintenance and system reconfigurations. As an example, the bayonet style connection makes it easy and simple to modify wafer support 34 to accommodate different sized wafers. In other words, the bayonet-connection allows disk 38 to be replaced with a different sized disk suitable for a different sized wafer. It becomes a simple matter of a bayonet-type disconnection and reconnection. Similarly, if maintenance needs to be performed on the process chamber, the upper section of wafer support 34 can be easily removed with a simple bayonet-type disconnection and after maintenance the wafer support can be fully re-installed with a simple bayonet-type connection.

In light of the present disclosure, those skilled in the art will understand that a variety of lever mechanisms can be used in embodiments of the present invention. Similarly, a variety of lever arms can be used in embodiments of the present invention. One design of a lever arm 74 used in an embodiment of the present invention is shown in FIG. 4. The view shown in FIG. 4 is the top view of lever arm 74. Lever arm 74 has a first end 74A comprising a two-pronged fork. Lever arm 74 has a second end 74B that also comprises a two-pronged fork. The two-pronged fork of end 74B is at about a 90-degree angle with respect to the two-pronged fork of end 74A. Because of the difference in orientation for end 74A and end 74B, FIG. 4 does not show the two prongs of the fork of end 74B.

FIG. 5 shows a side view of lever arm 74 presented in FIG. 4. The two prongs of the fork of end 74B can be seen in FIG. 5 but the two prongs of the fork of end 74A cannot be seen in the side view of FIG. 5 because of the difference in orientation for end 74A and end 74B.

Lever arm 74 having end 74A comprising a two-pronged fork can be connected with bushing 66 using end 74A. In a preferred embodiment, bushing 66 has a small diameter section 66b between two sections 66a with a large diameter. The two-prongs of the fork on end 74A are sufficiently spaced apart to fit around small diameter section 66b but are sufficiently close so that the two prongs on end 74A do not fit around the large diameter sections 66a of bushing 66, as shown in FIG. 1 and FIG. 1a. The fork of end 74A at least partially surrounds small section 66b of bushing 66 as shown and described in FIG. 1, FIG. 1a, and FIG. 2. In other words, the fork of end 74A captures bushing 66. The fork can be used to exert an upward or a downward force on bushing 66 by respectively contacting the large diameter sections 66a of bushing 66. Consequently, lever arm 74 can exert an upward or a downward force on stem 42 by way of bushing 66.

As another option, lever arm 74 can be connected with a linear actuator such as linear actuator described for the embodiment in FIG. 1. Specifically, lever arm 74, having end 74B comprising a two-pronged fork, can be connected with a linear actuator using the two-pronged fork on end 74B. In one embodiment, the linear actuator includes an extension, such as a substantially rigid pin or rod, arranged so that the extension fits between the two prongs of the fork on end 74B.

The operation of the wafer lift mechanism on a semiconductor wafer processing chamber is an essential part of the overall process operation. Consequently, the ability to monitor the wafer mechanism can be particularly valuable for general maintenance, calibration, and troubleshooting. Observing the performance of the wafer lift and rotation mechanism for many of the standard technologies can be difficult because the standard technologies frequently use a metal bellows as part of raising and lowering the wafer holder. However, some embodiments of the present invention provide the capability of monitoring the wafer lift mechanism by including a window in the housing containing the wafer lift components. In other words, since embodiments of the present invention do not require using a bellows, it is easy to install a window in the housing for viewing the operation of the lift mechanism and rotation mechanism.

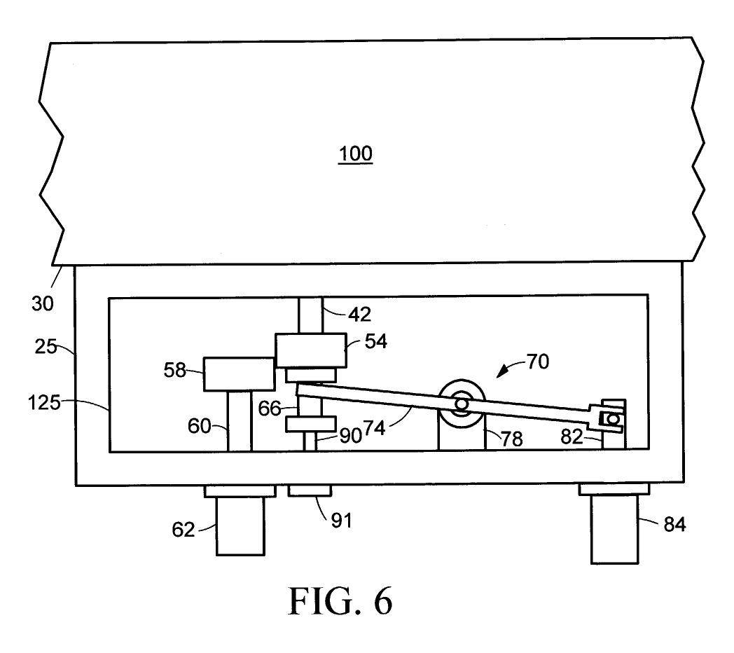

Reference is now made to FIG. 6 wherein there is shown an exterior side view of an embodiment of the present invention. FIG. 6 shows a portion of a process chamber 100 having a bottom surface 30. FIG. 6 also shows a housing 25 containing components of the wafer lift mechanism described in FIGS. 1-5. The wafer lift mechanism of FIG. 6 is essentially the same as that for the embodiments described in FIGS. 1 and 2. FIG. 6 also shows a window 125 that is incorporated as part of housing 25. Window 125 includes a substantially transparent material to allow viewing the interior of housing 25 for monitoring the components of the wafer lift mechanism. In one configuration, housing 25 has a view port and further includes a substantially transparent window material connected with the housing adjacent to the port for viewing the position of the lever.

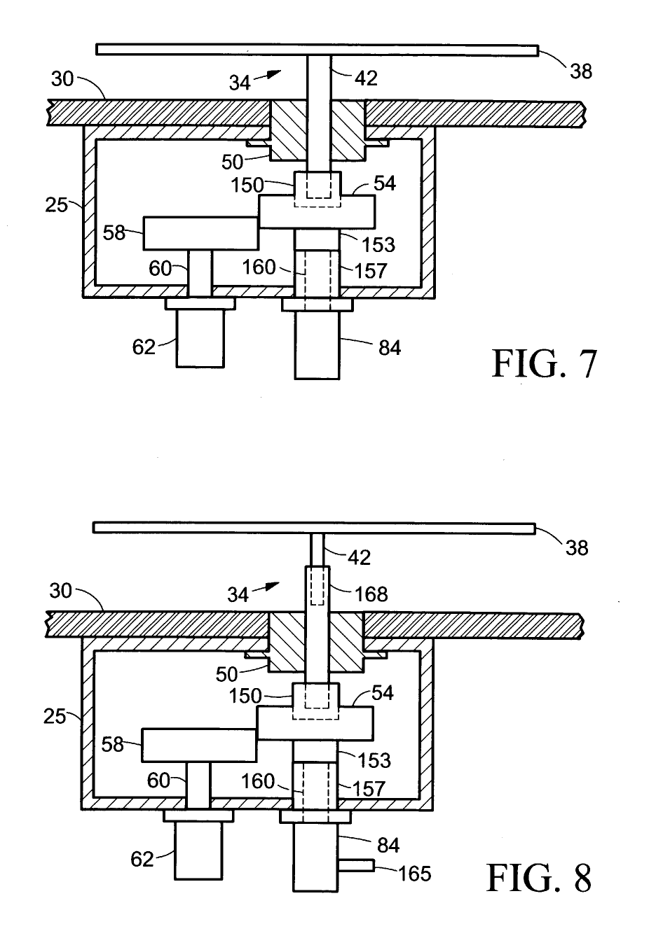

Reference is now made to FIG. 7 wherein there is shown an apparatus according to one embodiment of the present invention for processing a workpiece such as a semiconductor wafer. The apparatus includes a housing 25 shown in cross-section, a portion of a bottom surface 30 of a process chamber shown in cross-section, a wafer support 34, a disk 38, a wafer holder stem 42, a bushing 50, a spur gear 54, a spur gear 58, a shaft 60, a rotary motion feed through 62, and an air piston 84 that are all substantially the same as those described for the embodiments in FIG. 1 and FIG. 2.

Wafer support 34 is coupled to a rotary motion source to allow rotation of wafer support 34 so that the wafer can be rotated during processing. In one embodiment, rotary motion can be coupled to wafer support 34 using spur gears. FIG. 7 shows spur gear 54 connected with stem 42. The embodiment shown in FIG. 7 includes a bushing holder 150 for connecting stem 42 with spur gear 54. A variety of materials can be selected for bushing holder 150. Preferred choices are materials typically used for bushings. For the embodiment shown in FIG. 7, bushing holder 150, preferably, comprises a material such as stainless steel. Other examples of suitable materials are metals, metal alloys, and materials such as quartz. The most preferred materials are those that can be threaded.

In a preferred embodiment, bushing holder 150 is threaded and spur gear 54 is threaded so that bushing holder 150 and spur gear 54 can be threadably connected to allow adjustment of the height of wafer support 34 by adjusting the amount that bushing holder 150 and spur gear 54 are threaded together. The amount of threading can be substantially locked in-place using standard methods of locking such as using a setscrew and such as using a pin. Optionally, embodiments of the present invention may include spur gear 54 having a position locking mechanism such as a setscrew and such as a pin.

A second spur gear, spur gear 58, is engaged with spur gear 54. Shaft 60 for a rotary motion feedthrough 62 is coupled to housing 25 so as to provide a source of rotary motion to the interior of housing 25.

Spur gear 58 is connected with shaft 60 so that rotary motion of shaft 60 causes rotary motion for spur gear 58. Shaft 60 is coupled to rotary motion feedthrough 62. The rotary motion of spur gear 58 is coupled to spur gear 54 for rotating the wafer.

The apparatus shown in FIG. 7 is also capable of causing up-and-down motion of wafer support 34. Preferably, the up-and-down motion can be effected while wafer support 34 is still coupled to the rotary motion source. The embodiment shown in FIG. 7 achieves the up-and-down motion of wafer support 34 using a linear actuator. Examples of suitable linear actuators may include components such as air pistons, solenoid actuators, and linear motors.

In a preferred embodiment, the linear actuator includes an air piston 84. For the embodiment shown in FIG. 7, the linear actuator also includes a linear bearing 157 surrounding an actuator shaft 160. Air piston 84 is connected to housing 25 at a hole in the wall of housing 25 so that actuator shaft 160 can be operated to produce up-and-down motion by air piston 84 through the hole. Air piston 84 is connected with housing 25 so as to produce a substantially gas tight seal. Actuator shaft 160 is illustrated using dashed lines in FIG. 7. Linear bearing 157 is connected with housing 25 and aids in providing alignment and support for actuator shaft 160. Linear bearing 157 is optional and is not required for all embodiments of the present invention.

FIG. 7 also shows a rotation bearing 153. Rotation bearing 153 is coupled between actuator shaft 160 and spur gear 54 so that up-and-down motion produced by air piston 84 can be transferred through actuator shaft 160 and rotation bearing 153 to spur gear 54 to produce up-and-down motion for wafer support 34.

Reference is now made to FIG. 8 where there is shown an apparatus substantially the same as that described for FIG. 7. The embodiment shown in FIG. 8 includes wafer holder stem 42a and stem housing 168 replacing wafer holder stem 42 described in the embodiment shown in FIG. 7. Stem 42 is detachably connected with stem housing 168. In a preferred embodiment, stem housing 168 includes an axial bore into which at least a portion of wafer holder stem 42a fits therein.

Optionally, the bore in stem housing 168 may be shaped to form a keyway and wafer holder stem 42a may be shaped to serve as a key for the keyway.

FIG. 8 shows air piston 84 having a gas connection 165 for driving air piston 84. Air such as clean dry air may be used to drive air piston 84. However, in a preferred embodiment of the present invention, a process compatible gas is used to drive air piston 84 so that if there is a leak from air piston 84 into housing 25, the leaking gas will be process compatible. An example of a process compatible gas may be one of the elemental inert gases such as helium and argon. For some applications, gases such as nitrogen may be used instead of air. For applications where a reducing gas is required, then a gas such as hydrogen may be used to drive air piston 84. A preferred embodiment of the present invention includes a process chamber for epitaxial deposition of semiconductor layers in which piston 84 is connected with a supply of hydrogen gas for driving piston 84.

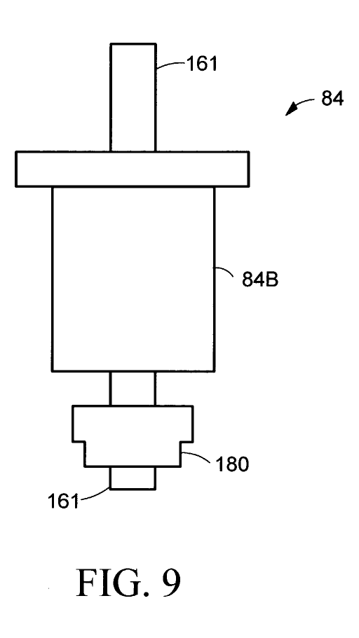

Reference is now made to FIG. 9 where there is shown a further embodiment of an air piston 84 that can be used in a preferred embodiment of a lift and rotation system that is substantially the same as that described for FIG. 7 and FIG. 8. Air piston 84 shown in FIG. 9 includes an elongated actuator shaft 161 that extends through the bottom of the air piston body 84B. In other words, actuator shaft 161 is substantially the same as that described for FIG. 7 and FIG. 8 with the exception that actuator shaft 161 is sufficiently long so as to extend through the bottom of the piston body housing so that one end portion of actuator shaft 161 is open to the ambient conditions. Air pistons with elongated shafts are commercially available from numerous vendors.

FIG. 9 also shows a stop mechanism 180 for limiting the range of motion for shaft 161: more specifically, for limiting the distance actuator shaft 161 can be move to lift the susceptor described for FIG. 7 and FIG. 8. Stop mechanism 180 is coupled to shaft 161 on the portion of shaft 161 that is open to the ambient. Preferably, stop mechanism 180 can be coupled to actuator shaft 161 at positions selected by a user and the coupling can be adjusted without exposing the interior of the lift and rotation apparatus to the ambient conditions. In other words, the range of motion for actuator shaft 161, and consequently the amount of lift for the susceptor, is adjustable from outside of the housing for the lift and rotation system and without opening the process chamber.

Combining stop mechanism 180 with air piston 84 in embodiments of the present invention improves the serviceability and versatility of the lift and rotation system. The combination can allow adjustments to the height for lifting without opening the process chamber or the lift housing. One benefit of this configuration is that the process chamber and the lift and rotation housing can be kept free of contamination when the lifting height is adjusted. Another benefit is that the lift height can be adjusted during actual process conditions; the adjustments can be made under the same conditions of temperature, pressure, and other process conditions for which the lift and rotation system will be used. For applications that involve high temperature processing of workpieces, variations caused by thermal expansion can be adjusted for with substantially no trial and error corrections or complex calculations.

A variety of designs can be used for the stop mechanism 180 and actuator shaft 161 combination. In a preferred embodiment, the portion of actuator shaft 161 that is open to the ambient is threaded so as to accommodate stop mechanism 180. Stop mechanism 180 includes a threaded jam nut in this embodiment. In other words, the jam nut is threadably coupled to the actuator shaft 161. The jam nut is screwed onto actuator shaft 161 to a selected position that provides the desired maximum lift height. Optionally, stop mechanism 180 may also include a spacer such as a washer that is positioned between the jam nut and the air piston body 84B. Of course, stop mechanism 180 is not limited to using a jam nut. In an alternative configuration, the actuator shaft 161 may not be threaded and stop mechanism 180 may include a set screw for attaching stop mechanism 180 to actuator shaft 161. Other configurations for actuator shaft 161 and stop mechanism 180 will be clear to those of ordinary skill in the art in view of the present disclosure.

Air piston 84 described in FIG. 9 is an example of a preferred embodiment. It is to be understood that linear actuators other than an air piston can be used as alternatives in the embodiment described in FIG. 9.

Clearly, embodiments of the present invention can be used with process chambers for a wide variety of processes for semiconductor device fabrication. The process conditions that can be produced by the process chamber will determine the types of applications for embodiments of the present invention. Changes in the selected process gases and process temperatures allow embodiments of the present invention to be suitable for semiconductor wafer processing steps such as annealing, activating dopant, depositing by chemical vapor deposition, depositing by epitaxial deposition, doping, forming a silicide, nitriding, oxidizing, reflowing a deposit, and recrystallizing.

As a particular example, embodiments of the present invention are suitable for use with semiconductor process chambers such as those described in U.S. Pat. No. 6,326,584, the content of which is incorporated in its entirety by this reference.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

While there have been described and illustrated specific embodiments of the invention, it will be clear that variations in the details of the embodiments specifically illustrated and described may be made without departing from the true spirit and scope of the invention as defined in the appended claims and their legal equivalents.

What is claimed is:

1. An apparatus for generating rotational and translational motion for processing a substrate, the apparatus comprising:
a housing;
a shaft;
a rotation bushing for holding the shaft, the bushing being connected with the housing, the shaft being coupled to the rotation bushing to allow axial rotational motion of the shaft and linear translational motion of the shaft, the shaft extending into the housing;
a rotary motion source;
a rotation coupling connected between the rotary motion source and the shaft so as to transfer rotary motion from the source to the shaft;
a pivot bearing connected with the housing for support;
a lever connected with the pivot bearing; and
a linear actuator connected with the housing and connected with the lever for causing movement of the lever about the pivot bearing, the lever being connected with the shaft so that movement of the lever about the pivot bearing causes translational motion of the shaft substantially along the axis of the shaft.

2. The apparatus of claim 1 wherein the housing has a view port and further comprising a substantially transparent window material connected with the housing adjacent to the port for viewing the position of the lever.

3. The apparatus of claim 1 wherein the housing has a port for receiving a purge gas.

4. The apparatus of claim 1 wherein the housing has a port for receiving a purge gas and the housing has a view port and further comprising a substantially transparent window material connected with the housing adjacent to the port.

5. The apparatus of claim 1 wherein the rotation bushing has a slot for allowing the purge gas to exit the housing.

6. The apparatus of claim 1 wherein the rotation coupling comprises at least one of a belt, a chain, and a gear.

7. The apparatus of claim 6 wherein the rotation coupling comprises a gear.

8. The apparatus of claim 1 wherein the linear actuator comprises a gas driven piston.

9. The apparatus of claim 1 wherein the rotary motion source comprises a rotary feedthrough connected with the housing so that rotary motion generated outside of the housing can be substantially reproduced within the housing so as to rotate the shaft.

10. The apparatus of claim 1 further comprising a rotation bearing connected between the shaft and the lever.

11. An apparatus for generating rotational and translational motion for a substrate for electronic or optical device fabrication, the apparatus comprising:
a susceptor for holding the substrate;
a rotatable stem connected with the susceptor for causing the susceptor to rotate;
a rotary motion source connected with the stem for causing rotation of the stem;
a linear actuator; and
a lever mechanism connected between the stem and the linear actuator so that linear motion from the actuator produces a linear translation motion of the stem and susceptor connected thereto.

12. The apparatus of claim 11 wherein the lever mechanism comprises a lever and a pivot bearing connected thereto.

13. The apparatus of claim 11 wherein the stem includes a first part for a bayonet-type connection; and wherein the stem includes a complementary part for a bayonet-type connection for bayonet-type connecting and bayonet-type disconnecting the first part and complementary part.

14. The apparatus of claim 13 further comprising a spring loaded plunger arranged to exert a force between the first part and the complementary part for stabilizing the bayonet-type connection.

15. The apparatus of claim 14 wherein the stem has a bore for substantially containing the spring-loaded plunger therein.

16. In a combination:
a chamber for processing a substrate;
a housing connected with the chamber;
a susceptor for holding a substrate substantially in the chamber;
a rotatable stem connected with the susceptor for causing the susceptor to rotate, the stem extending into the housing;
a rotary motion source connected with the stem at a location substantially within the housing for causing rotation of the stem;
a linear actuator connected with the housing so as to produce linear motion substantially within the housing; and
a lever mechanism connected between the stem and the linear actuator so that linear motion from the actuator produces a linear translation motion of the stem and susceptor connected thereto.

17. The apparatus of claim 16 wherein the housing has a view port and further comprising a substantially transparent window material connected with the housing adjacent to the port.

18. The apparatus of claim 16 wherein the housing has a gas connection for receiving a purge gas.

19. The apparatus of claim 16 wherein the housing has a gas connection for receiving a purge gas and the housing has a view port and further comprising a substantially transparent window material connected with the housing adjacent to the port.

20. The apparatus of claim 18 further comprising a rotation bushing and wherein the chamber has a hole for positioning the bushing therethrough so that the stem extends through the bushing from the chamber to the housing, the rotation bushing having a slot so that purge gas can exit the housing.

21. The apparatus of claim 16 wherein the chamber is configured for at least one of the processes of annealing, activating dopant, depositing by chemical vapor deposition, depositing by epitaxial deposition, doping, forming a silicide, nitriding, oxidizing, reflowing a deposit, and recrystallizing.

22. An apparatus for generating rotational and translational motion for processing a substrate, the apparatus comprising:
a housing;
a shaft;
a rotation bushing for holding the shaft, the bushing being connected with the housing, the shaft being coupled to the rotation bushing to allow axial rotational motion of the shaft and linear translational motion of the shaft, the shaft extending into the housing;
a rotary motion source;
a rotation coupling connected between the rotary motion source and the shaft so as to transfer rotary motion from the source to the shaft; and
a linear actuator connected with the housing and connected with the shaft so that movement produced by the linear actuator causes translational motion of the shaft substantially along the axis of the shaft.

23. The apparatus of claim 22 wherein the linear actuator comprises at least one of an air piston, a solenoid, and a linear motor.

24. The apparatus of claim 22 wherein the linear actuator is selected from the group of linear actuators consisting of air piston driven actuators, solenoid driven actuators, and linear motor driven actuators.

25. The apparatus of claim 22 wherein the linear actuator comprises an air piston.

26. The apparatus of claim 25 wherein the air piston is connected with a process compatible gas source for driving the air piston.

27. The apparatus of claim 25 wherein the air piston is connected with a hydrogen gas source for driving the air piston.

28. The apparatus of claim 22 wherein the linear actuator comprises an actuator body and an actuator shaft, the actuator shaft being sufficiently long so that one end of the actuator shaft extends through the actuator body to the exterior of the housing and further comprising a stop mechanism coupled to the actuator shaft at a location exterior to the housing, the stop mechanism being capable of limiting the range of motion for the actuator shaft.

29. The apparatus of claim 22 wherein the linear actuator comprises an air piston having an air piston body and an actuator shaft, the actuator shaft being sufficiently long so that one end of the actuator shaft extends through the air piston body to the exterior of the housing and further comprising a stop mechanism coupled to the actuator shaft at a location exterior to the housing, the stop mechanism being capable of limiting the range of motion for the actuator shaft.

30. The apparatus of claim 22 wherein the linear actuator comprises an air piston having an air piston body and an actuator shaft, the actuator shaft being sufficiently long so that one end of the actuator shaft extends through the air piston body to the exterior of the housing and further comprising a stop mechanism coupled to the actuator shaft at a location exterior to the housing, the stop mechanism being capable of limiting the range of motion for the actuator shaft, the stop mechanism comprising a jam nut threadably coupled to the actuator shaft.
